(19) United States
(12) Patent Application Publication
(10) Pub. No.: US 2006/0001329 A1
(43) Pub. Date: Jan. 5, 2006

(54) FBAR device frequency stabilized against temperature drift

(76) Inventors: Valluri Rao, Saratoga, CA (US); Qing Ma, San Jose, CA (US); Quan Tran, Fremont, CA (US); Dong Shim, San Jose, CA (US); Li-Peng Wang, Santa Clara, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/882,510

(22) Filed: Jun. 30, 2004

(51) Int. Cl. H01L 41/08

(52) U.S. Cl. 310/315

(57) ABSTRACT

A film bulk acoustic resonator (FBAR) comprises a piezoelectric film sandwiched between a top electrode and a bottom electrode. A temperature sensor is provided to sense a temperature to determine a temperature induced frequency drift for the FBAR. A voltage controller operatively connected to the temperature sensor supplies a direct current (DC) bias voltage to the FBAR to induce an opposite voltage induced frequency drift to compensate for the temperature induced frequency drift.

### FIELD OF THE INVENTION

Embodiments of the present invention relate to film bulk acoustic resonators (FBARs) and, more particularly to such devices stabilized against temperature drift.

### BACKGROUND INFORMATION

Film bulk acoustic resonator (FBAR) technology may be used as a basis for forming many of the frequency components in modern wireless systems. For example, FBAR technology may be used to form filter devices, oscillators, resonators, and a host of other frequency related components. FBAR may have advantages compared to other resonator technologies, such as Surface Acoustic Wave (SAW) and traditional crystal oscillator technologies. In particular, unlike crystals oscillators, FBAR devices may be integrated on a chip and typically have better power handling characteristics than SAW devices.

The descriptive name given to the technology, FBAR, may be useful to describe its general principals. In short, “Film” refers to a thin piezoelectric film such as Aluminum Nitride (AIN) sandwiched between two electrodes. Piezoelectric films have the property of mechanically vibrating in the presence of an electric field as well as producing an electric field if mechanically vibrated. “Bulk” refers to the body or thickness of the sandwich. When an alternating voltage is applied across the electrodes the film begins to vibrate. “Acoustic” refers to this mechanical vibration that resonates within the “bulk” (as opposed to just the surface in a SAW device) of the device.

The frequency characteristics of FBAR devices tend to be influenced by temperature which may be undesirable for wireless communication applications. For example, for cell phone applications, the operation temperature specification may be between −35 and +85° C. Such extreme temperature variations may be encountered for example in a closed automobile where a cell phone may be kept. Because of temperature induced frequency drift, pass band windows are typically designed appreciably larger than they otherwise would be and transition bands sharper. Such design constraints tend to degrade insertion loss and demand more stringent processing requirements leading to reduced production yield. These constraints may be illustrated in a current FBAR filter design where there is only a 12 MHz (mega-Hertz) frequency variation budget governed by communication standards and material properties. A temperature variation from −35 to +85° C. may induce a frequency drift in the FBAR filter that consumes about 6 MHz, thus leaving only 6 MHz for processing variations.

### BRIEF DESCRIPTION OF THE DRAWINGS

FIG. 1 is a cross-sectional view of a film bulk acoustic resonator (FBAR);

FIG. 2 is a schematic of an electrical circuit of the film bulk acoustic resonator (FBAR) shown in FIG. 1;

FIG. 3 is a graph illustrating the temperature induced frequency drift for an FBAR;

FIG. 4 is a graph illustrating the DC bias voltage induced frequency drift for an FBAR;

FIG. 5 is an example FBAR oscillator circuit including a bias voltage source for compensating for temperature induced frequency drift;

FIG. 6 is an example FBAR filter circuit including a bias voltage source for compensating for temperature induced frequency drift; and

FIG. 7 is an example physical lay-out for the FBAR filter circuit shown in FIG. 6.

### DETAILED DESCRIPTION

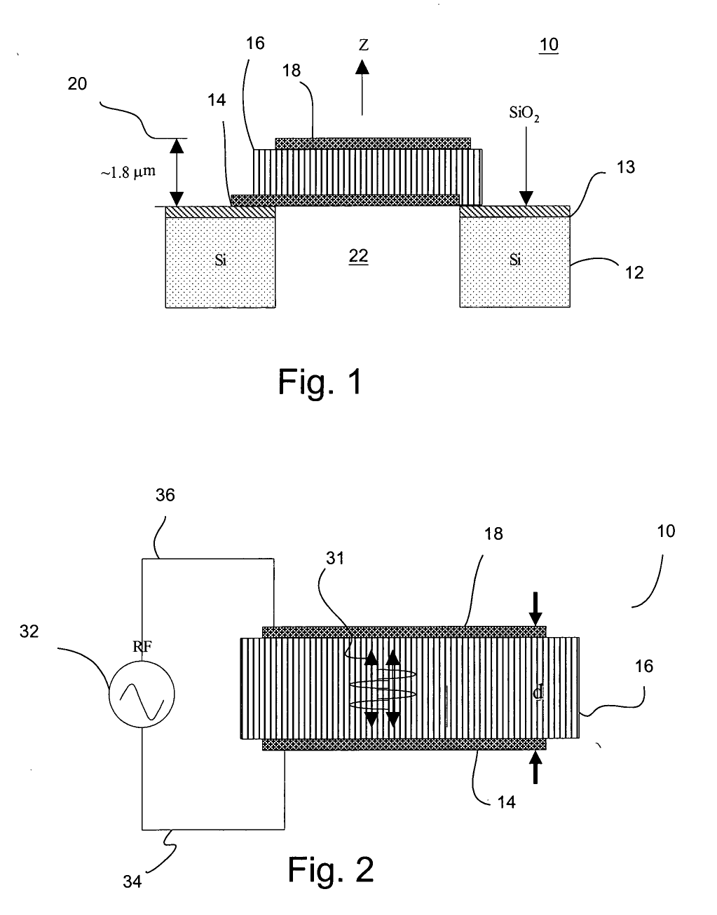

An FBAR device 10 is schematically shown in FIG. 1. The FBAR device 10 may be formed on the horizontal plane of a substrate 12, such as silicon and may include an SiO₂ layer 13. A first layer of metal 14 is placed on the substrate 12, and then a piezoelectric layer 16 is placed onto the metal layer 14. The piezoelectric layer 16 may be Zinc Oxide (ZnO), Aluminum Nitride (AIN), Lead Zirconate Titanate (PZT), or any other piezoelectric material. A second layer of metal 18 is placed over the piezoelectric layer 14. The first metal layer 14 serves as a first electrode 14 and the second metal layer 18 serves as a second electrode 18. The first electrode 14, the piezoelectric layer 16, and the second electrode 18 form a stack 20. As shown, the stack may be, for example, around 1.8 μm thick. A portion of the substrate 12 behind or beneath the stack 20 may be removed using back side bulk silicon etching to form an opening 22. The back side bulk silicon etching may be done using deep trench reactive ion etching or using a crystallographic-orientation-dependent etch, such as Potassium Hydroxide (KOH), Tetra-Methyl Ammonium Hydroxide (TMAH), and Ethylene-Diamene Pyrocatechol (EDP).

The resulting structure is a horizontally positioned piezoelectric layer 16 sandwiched between the first electrode 14 and the second electrode 16 positioned above the opening 22 in the substrate 12. In short, the FBAR 10 comprises a membrane device suspended over an opening 22 in a horizontal substrate 12.

FIG. 2 illustrates the schematic of an electrical circuit 30 which includes a film bulk acoustic resonator 10. The electrical circuit 30 includes a source of radio frequency “RF” voltage 32. The source of RF voltage 32 is attached to the first electrode 14 via electrical path 34 and attached to the second electrode 18 by the second electrical path 36. The entire stack 20 can freely resonate in the Z direction 31 when an RF voltage 32 at resonant frequency is applied. The resonant frequency is determined by the thickness of the membrane or the thickness of the piezoelectric layer 16 which is designated by the letter “d” or dimension “d” in FIG. 2. The resonant frequency is determined by the following formula:
f₀V/2d, where
f₀=the resonant frequency,
V=acoustic velocity of piezoelectric layer, and
d=the thickness of the piezoelectric layer.

It should be noted that the structure described in FIGS. 1 and 2 can be used either as a resonator or as a filter. To form an FBAR, piezoelectric films 16, such as ZnO, PZT and AIN, may be used as the active materials. The material properties of these films, such as the longitudinal piezoelectric coefficient and acoustic loss coefficient, are parameters for the resonator's performance. Performance factors include Q-factors, insertion loss, and the electrical/mechanical coupling. To manufacture an FBAR the piezoelectric film 16 may be deposited on a metal electrode 14 using for example reactive sputtering. The resulting films are polycrystalline with a c-axis texture orientation. In other words, the c-axis is perpendicular to the substrate.

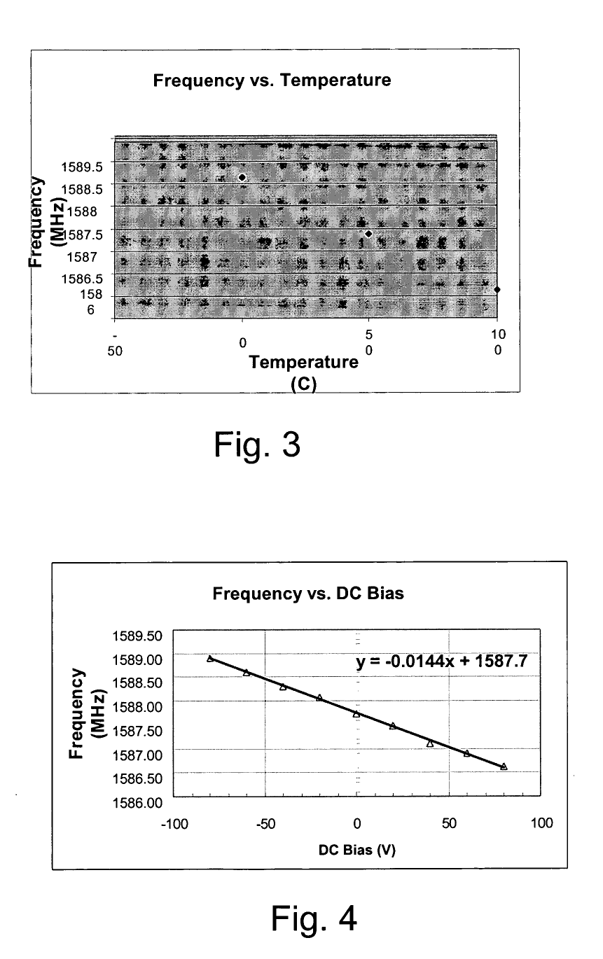

As previously noted, the frequency of the FBAR device 10 drifts with temperature. This is undesirable for most wireless applications since stable frequency characteristics over the range in which the device is expected to operate is preferred. FIG. 3 illustrates the drift phenomena. For a center frequency of about 1587 MHz at 50° C. the frequency of the FBAR device may drift up to 1589 MHz if the temperature drops to 0° C. and may drift down to 1586 MHz if the temperature rises to 100° C. The drift appears fairly linear over a given temperature range. While this drift may not be large, it may nevertheless be troubling for designers since modern wireless devices operate within tight frequency ranges. For an AIN based FBAR, the temperature coefficient of frequency (TCF), a, is about −25 ppm (parts per million) per degree Celsius.

According to embodiments of the invention, a direct current (DC) bias voltage may be applied across the FBAR device to compensate for temperature induced frequency drifts since the frequency of the FBAR may also be affected by a strong electric field in the piezoelectric film. For an AIN based FBAR at ˜1.6 GHz, the measured voltage coefficient of frequency (VCF), β, is ˜−9 ppm/Volt. It is inversely proportional to the AIN thickness (proportional to electric field strength), and consequently proportional to resonance frequency for a given bias voltage.

FIG. 4 illustrates the effects of a DC bias voltage to an FBAR device. It is noted that the voltage induced frequency drift between the DC voltage range of −100 to 100 Volts is approximately linear. In this example, for a center frequency of 1587.7 MHz, linear function may be expressed as y=−0.0144x+1587.7. Thus, according to embodiments of the invention, an applied DC bias voltage may be used to provide a voltage induced frequency drift in the opposite direction to compensate for the temperature induced frequency drift.

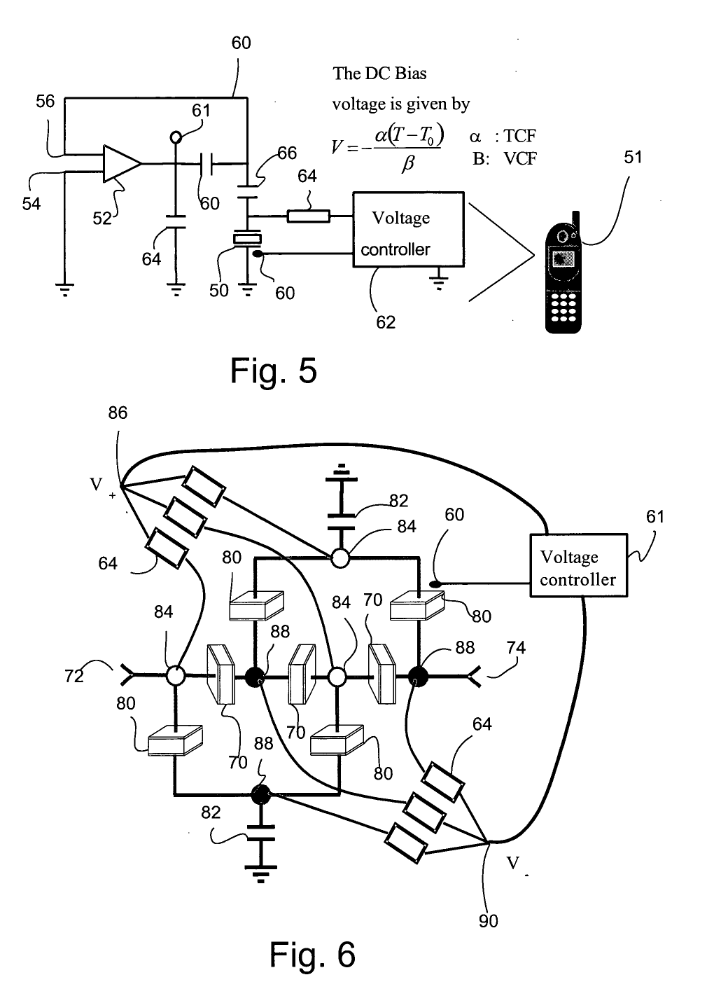

FIG. 5 shows a simple oscillator circuit using an FBAR 50. Oscillator circuits may be used in wireless devices such as cell phones 51. The oscillator may comprise an amplifier 52 having a first input 54 connected to ground and a second input 56 connected to a feedback loop 58 comprising a capacitor 60 connected to the output terminal 62 and a shunt capacitor 64 connected between the output terminal 62 and ground. A coupling capacitor 66 may connect the FBAR 50 to the feedback loop 58. A temperature sensor 60, such as a thermistor, may be placed in proximity to the FBAR 50 to detect the temperature influencing the FBAR 50. A controller 62 determines the DC bias voltage suitable to compensate to any temperature induced frequency drift of the FBAR 50. Thereafter, the appropriate DC Bias voltage may be applied to the FBAR 50. A high impedance RF choke or resistor 64 may be employed between the FBAR 50 and voltage source controller 62 to prevent shorting at high frequencies. The DC bias voltage may be calculated as:

$$V = \frac{α ( T - {T}_{o} )}{β}$$

Where, V=DC bias Voltage;
α=Temperature Coefficient of Frequency (TCF) for a given piezoelectric film;
β=Voltage Coefficient of Frequency (VCF) for a given piezoelectric film; and
T−Tₒ=a detected shift in temperature.

FIG. 6 shows FBAR devices used to form a filter such as may also be found in a wireless device. The particular filter shown is a ladder filter comprising a plurality of FBAR devices 70 connected in series between an input 72 and an output 74 and a plurality of FBAR devices 80 connected in parallel between the input 72 and output 74. Coupling capacitors 82 may be used between the parallel connected FBAR devices 80 and ground. As previously discussed, a temperature sensor 60 may be used to monitor the temperature influencing the FBAR devices 70 and 80 on a real time basis. A controller 62 may use the temperature data from the sensor 60 to calculate the DC bias voltage suitable to compensate for temperature induced frequency drift.

The ladder filter of FIG. 6 may be configured such that the piezoelectric polarization direction of all FBAR devices is the same. That is, nodes 84 indicated by an open circle are connected to the positive terminal 86 of the controller 62 and those nodes 88 indicated by a solid circle are connected to the negative terminal 90 of the controller 62 such that the DC electric field is applied in the same direction for all FBAR devices 70 and 80. The DC voltage may reverse polarity as the temperature changes to compensate for frequency drifts in either direction from a center frequency. Each node, 84 and 88, may be connected to the DC controller 62 via a high impedance radio frequency (RF) choke or resistor 64.

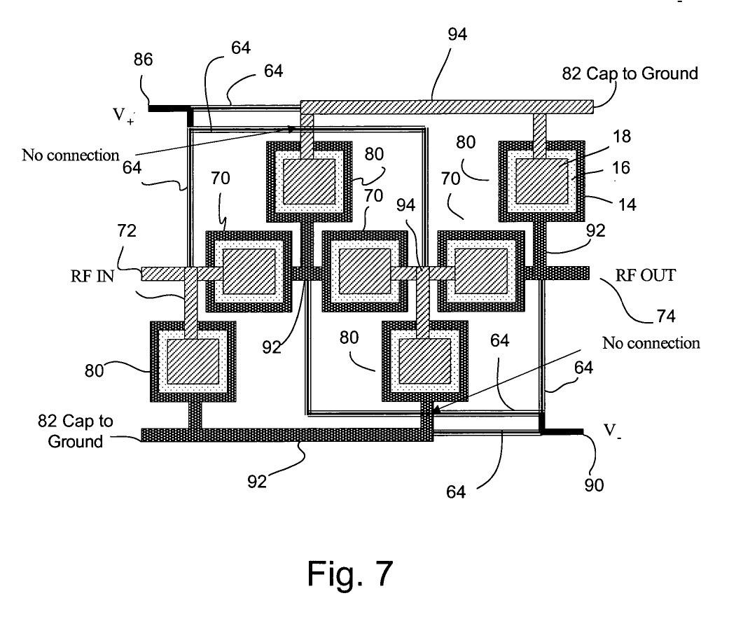

FIG. 7 shows an example physical layout for the ladder filter discussed with reference to FIG. 6 with like items from previously described figures labeled with like reference numerals. In particular, a plurality of serially connected FBAR devices 70 and parallel connected FBAR devices 80 are connected between an input 72 and an output 74. Each of the FBAR devices may comprise a bottom metal electrode 14, a piezoelectric film 16, and a top metal electrode 18. When depositing the piezoelectric film 16, the piezoelectric polarization direction of all resonators (70 and 80) is oriented either from bottom to top or from top to bottom, depending on the particular material. In this fashion, the top electrode 18 of an FBAR is connected to the top electrode of an adjacent FBAR. Similarly, the bottom electrode 14 of an FBAR is connected to the bottom electrode of an adjacent FBAR. While the layout may vary, the top electrodes 18 for each FBAR should be consistently connected to V+86 and bottom electrodes 14 connected to V−90 in order to shift the frequency of all FBAR devices (70 and 80) in the same direction for an applied bias voltage. The connection lines 92 and 94 may be made of low resistivity metals, such as Al, Au, Pt, Cu, Mo, or W. The high impedance radio frequency (RF) choke or resistor 64 may comprise impedance lines may be made from high resistivity materials, such as poly silicon, TiN.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

What is claimed is:

1. An apparatus, comprising:
a film bulk acoustic resonator (FBAR) comprising a piezoelectric film sandwiched between a top electrode and a bottom electrode;
a temperature sensor; and
a voltage source controller, operatively connected to the temperature sensor, to apply a direct current (DC) bias voltage across said top electrode and bottom electrode of said FBAR to compensate for temperature induced frequency drift.

2. The apparatus as recited in claim 1 further comprising:
two or more of the film bulk acoustic resonators (FBARs) operatively connected together;
the piezoelectric film in each of said two or more FBARs having a same polarization orientation;
the DC bias voltage across said top electrode and bottom electrode of said two or more FBARs having a same orientation.

3. The apparatus as recited in claim 1 wherein the DC bias voltage is selected as:
$$V = \frac{α ( T - {T}_{o} )}{β}$$
Where, V=DC bias Voltage;
α=Temperature Coefficient of Frequency (TCF) for a given piezoelectric film;
β=Voltage Coefficient of Frequency (VCF) for a given piezoelectric film; and
T−T₀=a shift in temperature.

4. The apparatus as recited in claim 1 further comprising:
a high impedance resistor connected between said voltage source controller and said FBAR.

5. The apparatus as recited in claim 1 wherein said apparatus comprises an oscillator circuit for a wireless device.

6. The apparatus as recited in claim 2 wherein said apparatus comprises a radio frequency (RF) filter.

7. A method, comprising:
sensing a temperature for a film bulk acoustic resonator (FBAR);
determining a temperature induced frequency drift for the FBAR;
determining a direct current (DC) bias voltage to compensate for the temperature induced frequency drift; and
applying the DC bias voltage to the FBAR.

8. The method as recited in claim 7 wherein the DC bias voltage is determined as:
$$V = \frac{α ( T - {T}_{o} )}{β}$$
Where, V=DC bias voltage;
α=Temperature Coefficient of Frequency (TCF) for a given piezoelectric film within the FBAR;
β=Voltage Coefficient of Frequency (VCF) for a given piezoelectric film; and
T−T₀=a shift in temperature.

9. The method as recited in claim 8, further comprising:
including the FBAR device in an oscillator circuit; and
supplying the DC bias voltage to the FBAR through a high impedance line.

10. The method as recited in claim 8, further comprising:
connecting a plurality of the FBARs in a circuit;
orienting a piezoelectric film within each of the FBARs to have a same polarization orientation; and
applying the DC bias voltage to each of the plurality of FBARs with a same voltage polarization.

11. The method as recited in claim 9, further comprising:
placing the oscillation circuit is within a wireless phone.

12. The method as recited in claim 10, wherein the circuit comprises a filter.

13. A system comprising:
a wireless communication device;
a film bulk acoustic resonator (FBAR) comprising a piezoelectric film sandwiched between a top electrode and a bottom electrode within a circuit in the wireless communication device;
a temperature sensor to sense a temperature to determine a temperature induced frequency drift for the FBAR; and
a voltage controller operatively connected to the temperature sensor to supply a direct current (DC) bias voltage to the FBAR to induce a voltage induced frequency drift to compensate for the temperature induced frequency drift.

14. The system as recited in claim 13, wherein said circuit comprises an oscillator circuit.

15. The system as recited in claim 13, wherein said circuit comprises a filter circuit.

16. The system as recited in claim 13 wherein the DC bias voltage is determined as:
$$V = \frac{α ( T - {T}_{o} )}{β}$$
Where, V=DC bias voltage;
α=Temperature Coefficient of Frequency (TCF) for a given piezoelectric film;
β=Voltage Coefficient of Frequency (VCF) for a given piezoelectric film; and
T−T₀=a shift in temperature.

17. The system as recited in claim 15 further comprising:
a plurality of FBARs each having the piezoelectric film having a same polarization orientation; and
the DC bias voltage connected to each of the plurality of FBARs with a same voltage polarization.

18. The system as recited in claim 13 further comprising:
a radio frequency choke to connect the DC bias voltage to the FBAR.

19. The system as recited in claim 13, wherein the temperature sensor comprises a thermistor.

20. The system as recited in claim 13 wherein the wireless communication device comprises a cell phone.
